(19) United States
(12) Patent Application Publication
(10) Pub. No.: US 2007/0298573 A1
(43) Pub. Date: Dec. 27, 2007

(54) SEMICONDUCTOR DEVICE AND METHOD FOR MANUFACTURING THE SAME

(76) Inventors: Chien-Ting Lin, Hsinchu City (TW); Liang-Wei Chen, Yilan County (TW); Che-Hua Hsu, Hsinchu County (TW); Guan-Hua Ma, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(21) Appl. No.: 11/309,094

(22) Filed: Jun. 22, 2006

(51) Int. Cl. H01L 21/336; H01L 21/4763

(52) U.S. Cl. 438/300; 438/649; 257/E21.634

(57) ABSTRACT

The invention is directed to a method for manufacturing a semiconductor device. The method comprises steps of forming a gate dielectric layer, a polysilicon layer and a patterned cap layer over a substrate sequentially and patterning the polysilicon layer to be a polysilicon gate by using the patterned cap layer as a mask. A plurality of lightly doped drain (LDD) regions are formed in the substrate aside the polysilicon gate, wherein a channel region is formed between the LDD regions in the substrate. A spacer is formed on the sidewall of the polysilicon gate and a source/drain region is formed in the substrate adjacent to the spacer. The patterned cap layer is removed and the spacer is removed. A metal silicidation process is performed for transforming the polysilicon gate into a metal silicide gate and forming a metal silicide layer at a surface of the source/drain region.

### BACKGROUND OF THE INVENTION

1. Field of Invention

The present invention relates to a semiconductor device and a method for manufacturing the same. More particularly, the present invention relates to a semiconductor device having a metal silicide gate and a method for manufacturing the same.

2. Description of Related Art

At the commencement of the invention of the semiconductor device, people are continuously seeking a way to decrease the size of the semiconductor device, that is, the number of the semiconductor devices within a unit area is increased, so that the operating efficiency can be improved.

The material of the gate holds one of the keys for continuously decreasing the size of the semiconductor device. Taking the complementary metal oxide semiconductor (CMOS) as an example, since poly-depletion effect and boron penetration happen while the polysilicon gate is used, it is difficult to apply the gate of polysilicon on the formation of the small size semiconductor. Therefore, the industry once brought out an idea for replacing the polysilicon gate with the metal gate. However, the use of metal as the material of the gate cannot full fill the requirement of the work function of the dual tunable for the PMOS and the NMOS in the CMOS. Hence, the use of metal as the material of the gate is not the best plan.

### SUMMARY OF THE INVENTION

Accordingly, at least one objective of the present invention is to provide a method for manufacturing a semiconductor device capable of obtaining a semiconductor device having a metal silicide gate.

At least another objective of the present invention is to provide a method for manufacturing a semiconductor device capable of obtaining a semiconductor device having a metal silicide gate without over metal silicidizing a source/drain region thereof.

The other objective of the present invention is to provide a semiconductor device having a metal silicide gate.

To achieve these and other advantages and in accordance with the purpose of the invention, as embodied and broadly described herein, the invention provides a method for manufacturing a semiconductor device. The method comprises steps of forming a gate dielectric layer, a polysilicon layer and a patterned cap layer over a substrate sequentially and patterning the polysilicon layer to be a polysilicon gate by using the patterned cap layer as a mask. A plurality of lightly doped drain (LDD) regions are formed in the substrate aside the polysilicon gate, wherein a channel region is formed between the LDD regions in the substrate. A spacer is formed on the sidewall of the polysilicon gate and a source/drain region is formed in the substrate adjacent to the spacer. The patterned cap layer is removed and the spacer is removed. A metal silicidation process is performed for transforming the polysilicon gate into a metal silicide gate and forming a metal silicide layer at a surface of the source/drain region.

According to the first embodiment of the present invention, when the material of the patterned cap layer is as same as the material of the spacer, the patterned cap layer is removed as the step of removing the spacer is performed.

According to the first embodiment of the present invention, the material of the substrate is selected from a group consisting of monocrystalline silicon, epitaxial silicon, germanium, germanium silicon, carbon silicon or the combination thereof.

According to the first embodiment of the present invention, the substrate includes a bulk substrate and a silicon-on-insulator substrate.

According to the first embodiment of the present invention, the material of the channel region is selected from a group consisting of monocrystalline silicon, epitaxial silicon, germanium, germanium silicon, carbon silicon or the combination thereof.

According to the first embodiment of the present invention, the material of the gate dielectric layer is selected from a group consisting of silicon oxide, silicon nitride, silicon oxy-nitride, a material with a dielectric constant higher than the silicon dioxide and the combination thereof.

According to the first embodiment of the present invention, the gate dielectric layer is made of material with high a dielectric constant.

According to the first embodiment of the present invention, the method for forming the source/drain region aside the spacer comprises an ion implantation process or a selective epitaxial deposition process.

According to the first embodiment of the present invention, the method for forming the source/drain region aside the spacer comprises removing a portion of the substrate aside the spacer to form a recession and then performing the selective epitaxial deposition process to form an epitaxy layer on the recession.

According to the first embodiment of the present invention, the selective epitaxial deposition process includes a vapor phase epitaxy process.

According to the first embodiment of the present invention, after the step of performing the metal silicidation process, the method further comprises forming a contact etching stopper layer (CESL).

According to the first embodiment of the present invention, after the step of forming the source/drain region in the substrate aside the spacer, the method further comprises performing a thermal annealing process or an epitaxial annealing process.

According to the first embodiment of the present invention, the materials of the metal silicide gate and the metal silicide layer comprise nickel silicide, titanium silicide or cobalt silicide.

The present invention also provides a method of manufacturing a semiconductor device. The method comprises steps of forming a gate dielectric layer and a polysilicon layer over the substrate sequentially and then forming a patterned cap layer on the polysilicon layer. The polysilicon layer is patterned to be a polysilicon gate by using the patterned cap layer as a mask and a plurality of LDD regions are formed in the substrate aside the polysilicon gate, wherein a channel region is formed between the LDD regions in the substrate. A spacer is formed on the sidewall of the polysilicon gate and a source/drain region is formed in the substrate aside the spacer. A first metal silicidation process is performed to form a metal silicide layer on a surface of the source/drain region. The patterned cap layer is removed and the spacer is removed. A second metal silicidation process is performed to transform the polysilicon gate into a metal silicide gate.

According to the second embodiment of the present invention, when the material of the patterned cap layer is as same as the material of the spacer, the patterned cap layer and spacer can be removed at the same time.

According to the second embodiment of the present invention, the material of the substrate is selected from a group consisting of monocrystalline silicon, epitaxial silicon, germanium, germanium silicon, carbon silicon or the combination thereof.

According to the second embodiment of the present invention, the substrate includes a bulk substrate and a silicon-on-insulator substrate.

According to the second embodiment of the present invention, the material of the channel region is selected from a group consisting of monocrystalline silicon, epitaxial silicon, germanium, germanium silicon, carbon silicon or the combination thereof.

According to the second embodiment of the present invention, the material of the gate dielectric layer is selected from a group consisting of silicon oxide, silicon nitride, silicon oxy-nitride, a material with a dielectric constant higher than the silicon dioxide and the combination thereof.

According to the second embodiment of the present invention, the gate dielectric layer is made of material with high a dielectric constant.

According to the second embodiment of the present invention, the method for forming the source/drain region aside the spacer comprises an ion implantation process or a selective epitaxial deposition process.

According to the second embodiment of the present invention, the method for forming the source/drain region aside the spacer comprises steps of removing a portion of the substrate aside the spacer to form a recession and performing the selective epitaxial deposition process to form an epitaxy layer on the recession.

According to the second embodiment of the present invention, the selective epitaxial deposition process includes a vapor phase epitaxy process.

According to the second embodiment of the present invention, after the step of performing the metal silicidation process, the method further comprises forming a contact etching stopper layer (CESL).

According to the second embodiment of the present invention, after the step of forming the source/drain region in the substrate aside the spacer, the method further comprises performing a thermal annealing process or an epitaxial annealing process.

According to the second embodiment of the present invention, the material of the metal silicide gate is either as same as or different from the material of the metal silicide layer.

According to the second embodiment of the present invention, the material of the metal silicide gate comprises nickel silicide, titanium silicide or cobalt silicide.

According to the second embodiment of the present invention, the material of the metal silicide layer comprises nickel silicide, titanium silicide or cobalt silicide.

The present invention further provides a semiconductor device. The semiconductor device comprises a substrate, a metal silicide gate, a gate dielectric layer, a channel region, an LDD region, a source/drain region and a metal silicide layer. The metal silicide gate is located on the substrate and the gate dielectric layer is located between the substrate and the metal silicide gate. The channel region is located in the substrate under the metal silicide gate and the LDD region is located in the substrate adjacent to the metal silicide gate. The source/drain region is located in the substrate adjacent to the LDD region and the metal silicide layer is located on a surface of the source/drain region.

According to the third embodiment of the present invention, the material of the substrate is selected from a group consisting of monocrystalline silicon, epitaxial silicon, germanium, germanium silicon, carbon silicon or the combination thereof.

According to the third embodiment of the present invention, the substrate includes a bulk substrate and a silicon-on-insulator substrate.

According to the third embodiment of the present invention, the semiconductor device further comprises an isolation structure located in the substrate outside the source/drain region.

According to the third embodiment of the present invention, the semiconductor device further comprises a well region located in the substrate under the metal silicide gate, the LDD region, and the source/drain region.

According to the third embodiment of the present invention, the material of the channel region is selected from a group consisting of monocrystalline silicon, epitaxial silicon, germanium, germanium silicon, carbon silicon or the combination thereof.

According to the third embodiment of the present invention, the material of the gate dielectric layer is selected from a group consisting of silicon oxide, silicon nitride, silicon oxy-nitride, a material with a dielectric constant higher than the silicon dioxide and the combination thereof.

According to the third embodiment of the present invention, the gate dielectric layer is made of material with high a dielectric constant.

According to the third embodiment of the present invention, the semiconductor device further comprises a contact etching stopper layer covering the substrate.

According to the third embodiment of the present invention, the material of the metal silicide gate is either as same as or different from the material of the metal silicide layer.

According to the third embodiment of the present invention, the material of the metal silicide gate comprises nickel silicide, titanium silicide or cobalt silicide.

According to the third embodiment of the present invention, the material of the metal silicide layer comprises nickel silicide, titanium silicide or cobalt silicide.

In the present invention, since the conventional polysilicon gate is replaced by the metal silicide gate, the poly-depletion effect and the boron penetration can be avoided during the size of the semiconductor device is decreased. In addition, a two-step metal silicidation process is used in the present invention so that the over metal silicidation of the source/drain can be avoided as the gate is metal silicidized. Besides, when the material of the patterned cap layer is as same as the material of the spacer, the patterned cap layer and the spacer can be removed in the same step so that the manufacturing process is simplified and the selectivity of the manufacturing process is increased.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a flow chart showing a method for manufacturing a semiconductor device according to a first embodiment of the invention.

FIG. 2 is a cross-sectional view of a structure of a semiconductor device according to a second embodiment of the present invention.

FIGS. 3A through 3I are cross-sectional views showing a method for manufacturing the semiconductor device shown in FIG. 2.

FIG. 4 is a cross-sectional view showing a structure of a semiconductor device according to a third embodiment of the present invention.

### DESCRIPTION OF THE PREFERRED EMBODIMENTS

### First Embodiment

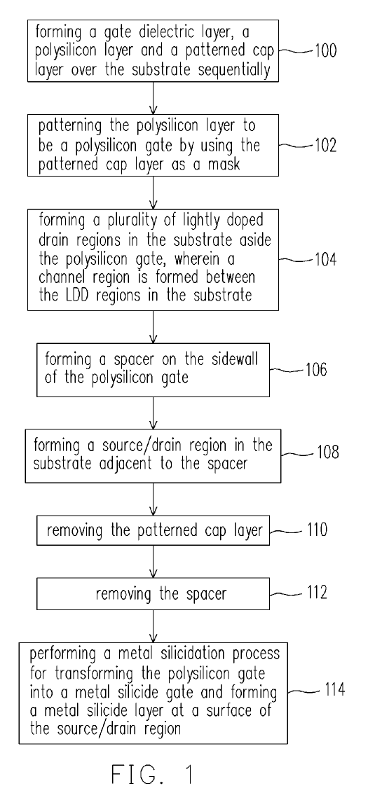

FIG. 1 is a flow chart showing a method for manufacturing a semiconductor device according to a first embodiment of the invention.

As shown in FIG. 1, in the step 100, a gate dielectric layer, a polysilicon layer and a patterned cap layer are formed over a substrate sequentially. The material of the substrate can be, for example, selected from a group consisting of monocrystalline silicon, epitaxial silicon, germanium, germanium silicon, carbon silicon or the combination thereof. The substrate can be also a bulk substrate or silicon-on-insulator substrate.

In the step 100, the gate dielectric layer can be, for example but not limited to, selected from a group consisting of silicon oxide, silicon nitride, silicon oxy-nitride, material with a dielectric constant higher than that of silicon dioxide or the combination thereof. Furthermore, the gate dielectric layer can be, for example, made of material with high a dielectric constant such as ZrO2, Si3N4 or HfSiNO.

In the step 102, by using the patterned cap layer as a mask, the polysilicon layer is patterned to form a polysilicon gate. The method for patterning the polysilicon layer can be, for example, a dry etching process in which the surface of the device is bombarded by plasma to perform the so-called ion bombardment to remove a portion of the polysilicon exposed by the patterned cap layer.

In the step 104, several lightly doped drain (LDD) regions are formed in the substrate adjacent to the polysilicon gate so as to form a channel region in the substrate between the LDD regions. Because of the formation of the LDD regions, the hot electron effect on the short channel metal-oxide semiconductor device can be alleviated. The material of the channel region can be, for example, selected from a group consisting of monocrystalline silicon, epitaxial silicon, germanium, germanium silicon, carbon silicon or the combination thereof.

The purpose of the step 106 is to form a spacer on the sidewall of the polysilicon gate. It should be noticed that when the materials of the spacer and the cap layer are the same, the spacer can be removed at the time the cap layer is removed. On the other hand, if the spacer is made of a material different from the material of the cap layer, the spacer and the cap layer should be removed in different steps.

Thereafter, in the step 108, a source/drain region is formed in the substrate adjacent to the spacer. There are two ways to form the source/drain region. One is an ion implantation process and the other is a selective epitaxial deposition process. In the selective epitaxial deposition process, a portion of the substrate aside the spacer and the polysilicon gate is removed to form a recession and then an epitaxy layer is formed in the recession to be the source/drain region. Further, this epitaxial deposition process includes a vapor phase epitaxy process. Besides, before the spacer is formed, a thin liner layer can be formed on the sidewall of the gate. After the source/drain region is formed, a thermal annealing process or an epitaxial annealing process is performed.

Then, in the step 110, a cap layer is removed. Thereafter, in the step 112, the spacer is removed. As mentioned above, when the cap layer is made of a material different from the material of the spacer, the step 110 and the step 112 should be performed individually. On the other hand, when the cap layer and the spacer are made of the same material, the step 110 and the step 112 can performed together.

In the step 114, a metal silicidation process is performed for completely transforming the polysilicon gate into a metal silicide gate and forming a metal silicide layer on the surface of the source/drain region. In this metal silicidation process, a metal layer, such as a nickel layer, a titanium layer or a cobalt layer, is formed over the surface of the device and then a thermal process is performed on the metal layer to initialize a silicidation on a portion of the silicon in contact with the metal so as to form the metal silicide layer. The material of this metal silicide layer can be nickel silicide, titanium silicide or cobalt silicide. Then, the rest portion of the metal layer which is not reacted with the silicon is removed.

After the step 114, a contact etching stopper layer is formed over the substrate to adjust the stress of the semiconductor device.

In the first embodiment, the semiconductor device possesses the gate made of metal silicide so that the poly-depletion effect and the boron penetration happening in the conventional device with the polysilicon gate can be avoided. Moreover, the chemical mechanical polish process is not involved with the manufacturing process according to the present invention so that the uniformity of the wafer can be improved and the efficiency and the simplification of the manufacturing process can be well improved as well.

### Second Embodiment

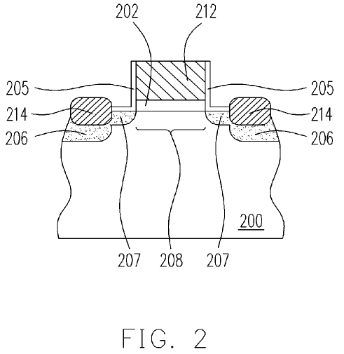

FIG. 2 is a cross-sectional view of a structure of a semiconductor device according to a second embodiment of the present invention. As shown in FIG. 2, the semiconductor device in the second embodiment comprises at least a substrate 200, a gate dielectric layer 202, a source/drain region 06, an LDD region 207, a channel region 208, a metal silicide gate 212 and a metal silicide layer 214. The metal silicide gate 212 is located on the substrate 200 and the gate dielectric layer 202 is located between the substrate 200 and the metal silicide gate 212. Furthermore, the channel region 208 is located in the substrate 200 under the metal silicide gate 212 and the LDD region is located in the substrate 200 adjacent to both sides of the metal silicide gate 212. Additionally, the source/drain region 206 is located in the substrate 200 adjacent to the LDD region 207 and the metal silicide layer 214 is located on the surface of the source/drain region 206. Moreover, a liner layer 205 is commonly located over the top of the gate.

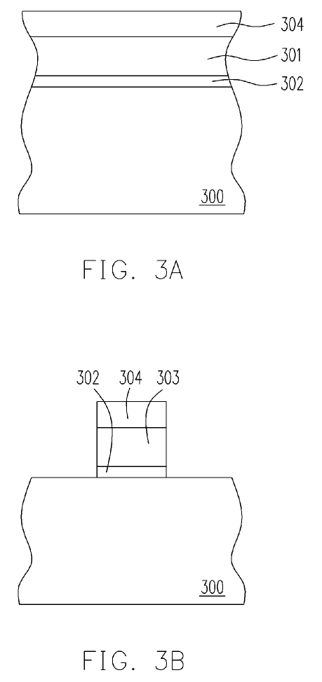

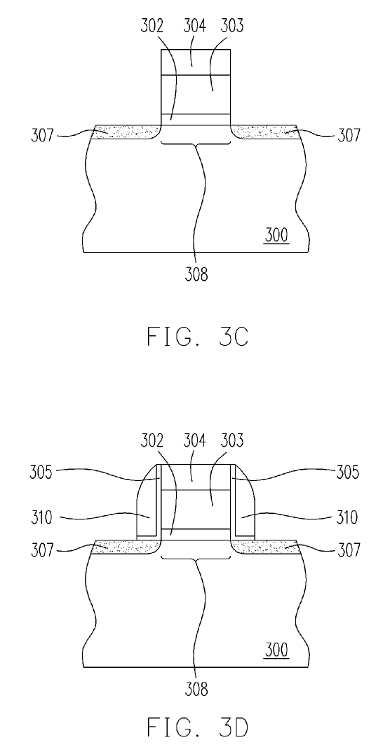

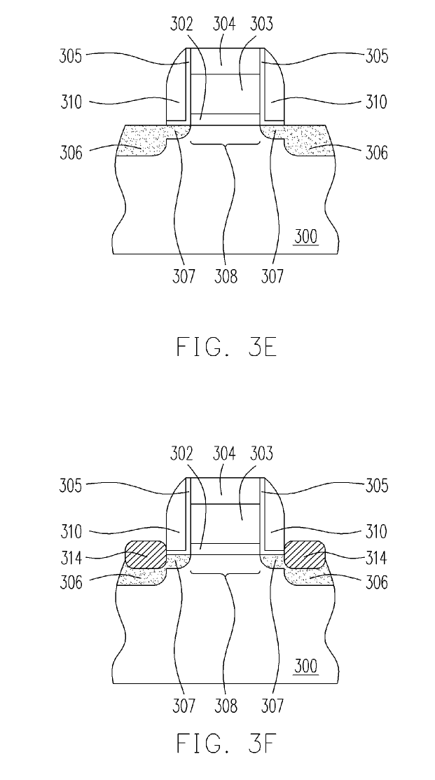

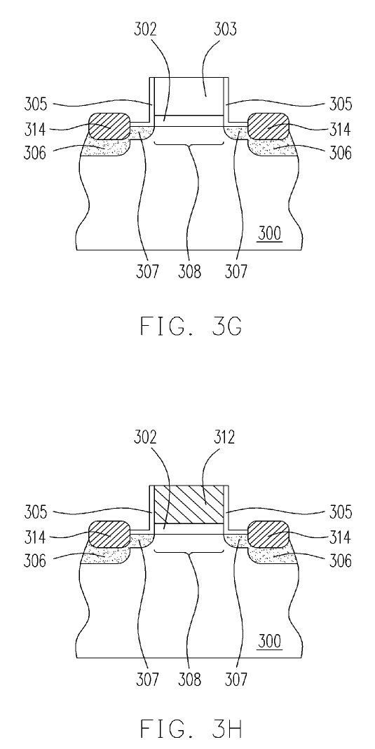

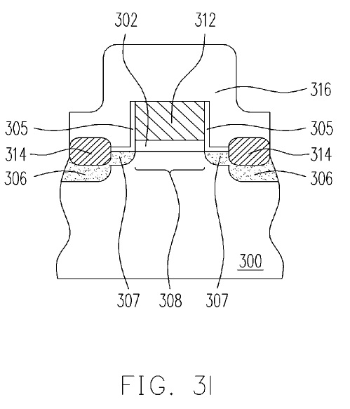

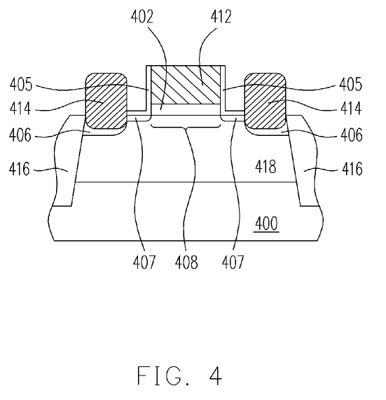

FIGS. 3A through 3I are cross-sectional views showing a method for manufacturing the semiconductor device shown in FIG. 2.

As shown in FIG. 3A, a gate dielectric layer 302, a polysilicon layer 301 and a patterned cap layer 304 are formed over the substrate 300 sequentially. The material of the substrate 300 can be, for example, selected from a group consisting of monocrystalline silicon, epitaxial silicon, germanium, germanium silicon, carbon silicon or the combination thereof. Furthermore, the substrate 300 can be also a bulk substrate or silicon-on-insulator substrate. Moreover, the material of the gate dielectric layer 302 can be, for example, selected from a group consisting of silicon oxide, silicon nitride, silicon oxy-nitride, a material with a dielectric constant higher than the silicon dioxide and the combination thereof. Additionally, the gate dielectric layer 302 can be, for example, made of material with high a dielectric constant such as ZrO2, Si3N4 or HfSiNO.

As shown in FIG. 3B, by using the patterned cap layer 304 as a mask, the polysilicon layer 301 (shown in FIG. 3A) is patterned to be a polysilicon gate 303. The method for patterning the polysilicon layer 301 can be, for example, a dry etching process in which the surface of the device is bombarded by plasma to perform the so-called ion bombardment to remove a portion of the polysilicon exposed by the patterned cap layer 304.

As shown in FIG. 3C, several lightly doped drain (LDD) regions 307 are formed in the substrate 300 adjacent to the polysilicon gate 303 so as to form a channel region 308 in the substrate 300 between the LDD regions 307. Because of the formation of the LDD regions 307, the hot electron effect on the short channel metal-oxide semiconductor device can be alleviated. The material of the channel region 308 can be, for example, selected from a group consisting of monocrystalline silicon, epitaxial silicon, germanium, germanium silicon, carbon silicon or the combination thereof.

As shown in FIG. 3D, a spacer 310 is formed on the sidewall of the polysilicon gate 303. Furthermore, before the spacer 310 is formed, a thin liner layer 305 can be also formed on the sidewall of the polysilicon gate 303.

As shown in FIG. 3E, a source/drain region 306 is formed in the substrate 300 adjacent to the spacer 310. There are two ways to form the source/drain region 306. One is an ion implantation process and the other is a selective epitaxial deposition process. In the selective epitaxial deposition process, a portion of the substrate 300 aside the spacer 310 and the polysilicon gate 303 is removed to form a recession and then an epitaxy layer is formed in the recession to be the source/drain region 306. Alternatively, the selective epitaxial deposition for forming the epitaxy layer comprises directly depositing the epitaxy layer on the surface of the substrate 300. Further, this epitaxial deposition process includes a vapor phase epitaxy process. After the source/drain region 306 is formed, a thermal annealing process or an epitaxial annealing process is performed.

As shown in FIG. 3F, a first metal silicidation process is performed for completely transforming the surface of the source/drain region 306 into a metal silicide layer 314. The method for forming the metal silicide layer 314 can, for example, comprises forming a metal layer, such as a nickel layer, a titanium layer or a cobalt layer, over the substrate 300 and then performing a thermal process on the metal layer to initialize a silicidation on a portion of the silicon in contact with the metal so as to form the metal silicide layer. The material of this metal silicide layer 314 can be nickel silicide, titanium silicide or cobalt silicide.

As shown in FIG. 3G, the patterned cap layer 304 over the surface of the polysilicon gate 303 is removed. In this step, when the patterned cap layer 304 and the spacer 310 are made of different materials, the step for removing the patterned cap layer 304 and the step for removing the spacer 310 can be performed individually. On the other hand, when the patterned cap layer 304 and the spacer 310 are made of the same material, the patterned cap layer 304 and the spacer 310 can be removed at the same time. In FIG. 3G, it is clear that the surface of the polysilicon gate 303 is no longer protected by the patterned cap layer 304.

As shown in FIG. 3H, similar to the description according to FIG. 3F, a second metal silicidation process is performed for completely transforming the polysilicon gate 303 into a metal silicide gate 312. In the second metal silicidation process, the material of a second metal layer used for forming the metal silicide material can be either as same as or different from the material of the first metal layer.

As shown in 3I, after the second metal silicidation process, a contact etching stopper layer 316 can be selectively formed to cover the substrate 300 to adjust the stress of the semiconductor device.

The second embodiment uses two-step metal silicidation process which is different from the first embodiment. When the metals used in the two metal silicidation processes are the same, the source/drain region is metal silicidized at the time the polysilicon gate is metal silicidized. It should be noticed that the silicidation depth of the source/drain region is proportional to the silicidation depth of the polysilicon gate. Since the thickness of the polysilicon gate is about 60˜120 nanometers which is much thicker than the source/drain region, the metal silicidizing the polysilicon gate and the source/drain region at the same time leads to over metal silicidation phenomenon of the source/drain region.

In the second embodiment, by using two-step metal silicidation process and properly removing the patterned cap layer, the aforementioned over metal silicidation phenomenon can be avoided. Furthermore, by using the selective epitaxial deposition process, the growing-upward source/drain with a relatively large thickness can be obtained. The advantage of this kind of structure is that the thick source/drain region can be used to balance the over metal silicidation during one-step metal silicidation process is performed. Therefore, the efficiency and the simplification of the manufacturing process can be well improved.

### Third Embodiment

FIG. 4 is a cross-sectional view showing a structure of a semiconductor device according to a third embodiment of the present invention. As shown in FIG. 4, the main structure of the semiconductor device comprises a substrate 400, a gate dielectric layer 402, a source/drain region 406, an LDD region 407, a channel region 408, a metal silicide gate 412, a metal silicide layer 414 and an isolation structure 416. The metal silicide gate 412 is located on the substrate 400 and the gate dielectric layer 402 is located between the substrate 400 and the metal silicide gate 412. Moreover, the channel region 408 is located in the substrate 400 under the metal silicide gate 412 and the LDD region 407 is located in the substrate 400 adjacent to the metal silicide gate 412. Furthermore, the source/drain region 406 is located in the substrate 400 adjacent to the LDD region 407. Additionally, the metal silicide layer 414 is located at the surface of the source/drain region 406.

As shown in 4, the material of the substrate 400 can be, for example, selected from a group consisting of monocrystalline silicon, epitaxial silicon, germanium, germanium silicon, carbon silicon or the combination thereof. Furthermore, the substrate 400 can be also a bulk substrate or silicon-on-insulator substrate. Moreover, the material of the gate dielectric layer 402 can be, for example, selected from a group consisting of silicon oxide, silicon nitride, silicon oxy-nitride, a material with a dielectric constant higher than the silicon dioxide and the combination thereof. Additionally, the gate dielectric layer 402 can be, for example, made of material with high a dielectric constant such as ZrO2, Si3N4 or HfSiNO. The material of the channel region 408 can be, for example, selected from a group consisting of monocrystalline silicon, epitaxial silicon, germanium, germanium silicon, carbon silicon or the combination thereof.

As for the formation of the source/drain region 406, the selective epitaxial deposition process is used to form the source/drain region 406 in this embodiment. In the selective epitaxial deposition process, a portion of the substrate 400 aside the LDD region 407 is removed to form a recession and then an epitaxy layer with a certain thickness is formed in the recession to complete the so-called recess epitaxy process. Alternatively, the selective epitaxial deposition for forming the source/drain region 406 comprises directly depositing the epitaxy layer on the surface of the substrate 300 to complete the so-called planner epitaxy process without forming any recession. Moreover, when the epitaxial deposition process is used to form the source/drain region 406, the thickness of the source/drain region 406 should be slightly larger than that of the metal silicide gate 412 to prevent the source/drain region 406 from being over metal silicidized during the metal silicidation process. In this embodiment, the material of the metal silicide gate 412 can be either as same as or different from the material of the metal silicide layer 414. Additionally, a contact etching stopper layer can be also formed to cover the substrate 400 to adjust the stress of the semiconductor device. In addition, outside of the source/drain region 406 further comprises an isolation structure 416 formed on the substrate 400. Moreover, the structure shown in FIG. 4 further comprises a well region 418 formed in the substrate 400 under the metal silicide gate 412, the LDD region 407 and the source/drain region 406. Further, a liner layer 405 is commonly formed on the surface of the metal silicide gate 412.

Altogether, in the method of the present invention, the gate is transforming into the metal silicide gate by using the metal silicidation process so that the problems of applying the polysilicon gate and metal gate onto the small size semiconductor device can be overcome. In addition, by using two-step metal silicidation process, the patterned cap layer and the spacer can be properly removed to overcome the problem of simultaneously metal silicidation of the gate and the source/drain region and the problem of over metal silicidation of the source/drain region. Furthermore, when the patterned cap layer is made of a material as same as the material of the spacer, the patterned cap layer and the spacer can be removed in the same step so as to simplify the manufacturing process.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

What is claimed is:

1. A method for manufacturing a semiconductor device, comprising:
forming a gate dielectric layer, a polysilicon layer and a patterned cap layer over a substrate sequentially;
patterning the polysilicon layer to be a polysilicon gate by using the patterned cap layer as a mask;
forming a plurality of lightly doped drain (LDD) regions in the substrate aside the polysilicon gate, wherein a channel region is formed between the LDD regions in the substrate;
forming a spacer on the sidewall of the polysilicon gate;
forming a source/drain region in the substrate adjacent to the spacer;
removing the patterned cap layer;
removing the spacer; and
performing a metal silicidation process for transforming the polysilicon gate into a metal silicide gate and forming a metal silicide layer at a surface of the source/drain region.

2. The method of claim 1, wherein, when the material of the patterned cap layer is as same as the material of the spacer, the patterned cap layer is removed as the step of removing the spacer is performed.

3. The method of claim 1, wherein the material of the substrate is selected from a group consisting of monocrystalline silicon, epitaxial silicon, germanium, germanium silicon, carbon silicon or the combination thereof.

4. The method of claim 1, wherein the substrate includes a bulk substrate and a silicon-on-insulator substrate.

5. The method of claim 1, wherein the material of the channel region is selected from a group consisting of monocrystalline silicon, epitaxial silicon, germanium, germanium silicon, carbon silicon or the combination thereof.

6. The method of claim 1, wherein the material of the gate dielectric layer is selected from a group consisting of silicon oxide, silicon nitride, silicon oxy-nitride, a material with a dielectric constant higher than the silicon dioxide and the combination thereof.

7. The method of claim 1, wherein the gate dielectric layer is made of material with high a dielectric constant.

8. The method of claim 1, wherein the method for forming the source/drain region aside the spacer comprises an ion implantation process or a selective epitaxial deposition process.

9. The method of claim 8, wherein the method for forming the source/drain region aside the spacer comprises:
removing a portion of the substrate aside the spacer to form a recession; and
performing the selective epitaxial deposition process to form an epitaxy layer on the recession.

10. The method of claim 8, wherein the selective epitaxial deposition process includes a vapor phase epitaxy process.

11. The method of claim 1, after the step of performing the metal silicidation process, further comprising forming a contact etching stopper layer (CESL).

12. The method of claim 1, after the step of forming the source/drain region in the substrate aside the spacer, further comprising performing a thermal annealing process or an epitaxial annealing process.

13. The method of claim 1, wherein the materials of the metal silicide gate and the metal silicide layer comprise nickel silicide, titanium silicide or cobalt silicide.

14. A method of manufacturing a semiconductor device, comprising:
forming a gate dielectric layer and a polysilicon layer over the substrate sequentially;
forming a patterned cap layer on the polysilicon layer;
patterning the polysilicon layer to be a polysilicon gate by using the patterned cap layer as a mask;
forming a plurality of LDD regions in the substrate aside the polysilicon gate, wherein a channel region is formed between the LDD regions in the substrate;
forming a spacer on the sidewall of the polysilicon gate;
forming a source/drain region in the substrate aside the spacer;
performing a first metal silicidation process to form a metal silicide layer on a surface of the source/drain region;
removing the patterned cap layer;
removing the spacer; and
performing a second metal silicidation process to transform the polysilicon gate into a metal silicide gate.

15. The method of claim 14, wherein, when the material of the patterned cap layer is as same as the material of the spacer, the patterned cap layer and spacer can be removed at the same time.

16. The method of claim 14, wherein the material of the substrate is selected from a group consisting of monocrystalline silicon, epitaxial silicon, germanium, germanium silicon, carbon silicon or the combination thereof.

17. The method of claim 14, wherein the substrate includes a bulk substrate and a silicon-on-insulator substrate.

18. The method of claim 14, wherein the material of the channel region is selected from a group consisting of monocrystalline silicon, epitaxial silicon, germanium, germanium silicon, carbon silicon or the combination thereof.

19. The method of claim 14, wherein the material of the gate dielectric layer is selected from a group consisting of silicon oxide, silicon nitride, silicon oxy-nitride, a material with a dielectric constant higher than the silicon dioxide and the combination thereof.

20. The method of claim 14, wherein the gate dielectric layer is made of material with high a dielectric constant.

21. The method of claim 14, wherein the method for forming the source/drain region aside the spacer comprises an ion implantation process or a selective epitaxial deposition process.

22. The method of claim 21, wherein the method for forming the source/drain region aside the spacer comprises:
removing a portion of the substrate aside the spacer to form a recession; and
performing the selective epitaxial deposition process to form an epitaxy layer on the recession.

23. The method of claim 21, wherein the selective epitaxial deposition process includes a vapor phase epitaxy process.

24. The method of claim 14, after the step of performing the metal silicidation process, further comprising forming a contact etching stopper layer (CESL).

25. The method of claim 14, after the step of forming the source/drain region in the substrate aside the spacer, further comprising performing a thermal annealing process or an epitaxial annealing process.

26. The method of claim 14, wherein the material of the metal silicide gate is either as same as or different from the material of the metal silicide layer.

27. The method of claim 14, wherein the material of the metal silicide gate comprises nickel silicide, titanium silicide or cobalt silicide.

28. The method of claim 14, wherein the material of the metal silicide layer comprises nickel silicide, titanium silicide or cobalt silicide.

29. A semiconductor device, comprising:
a substrate;
a metal silicide gate located on the substrate;
a gate dielectric layer located between the substrate and the metal silicide gate;
a channel region located in the substrate under the metal silicide gate;
an LDD region located in the substrate adjacent to the metal silicide gate;
a source/drain region located in the substrate adjacent to the LDD region; and
a metal silicide layer located on a surface of the source/drain region.

30. The semiconductor device of claim 29, wherein the material of the substrate is selected from a group consisting of monocrystalline silicon, epitaxial silicon, germanium, germanium silicon, carbon silicon or the combination thereof.

31. The semiconductor device of claim 29, wherein the substrate includes a bulk substrate and a silicon-on-insulator substrate.

32. The semiconductor device of claim 29 further comprising an isolation structure located in the substrate outside the source/drain region.

33. The semiconductor device of claim 29 further comprising a well region located in the substrate under the metal silicide gate, the LDD region, and the source/drain region.

34. The semiconductor device of claim 29, wherein the material of the channel region is selected from a group consisting of monocrystalline silicon, epitaxial silicon, germanium, germanium silicon, carbon silicon or the combination thereof.

35. The semiconductor device of claim 29, wherein the material of the gate dielectric layer is selected from a group consisting of silicon oxide, silicon nitride, silicon oxy-nitride, a material with a dielectric constant higher than the silicon dioxide and the combination thereof.

36. The semiconductor device of claim 29, wherein the gate dielectric layer is made of material with high a dielectric constant.

37. The semiconductor device of claim 29 further comprising a contact etching stopper layer covering the substrate.

38. The semiconductor device of claim 29, wherein the material of the metal silicide gate is either as same as or different from the material of the metal silicide layer.

39. The semiconductor device of claim 29, wherein the material of the metal silicide gate comprises nickel silicide, titanium silicide or cobalt silicide.

40. The semiconductor device of claim 29, wherein the material of the metal silicide layer comprises nickel silicide, titanium silicide or cobalt silicide.
